(19) United States
(12) Patent Application Publication
(10) Pub. No.: US 2020/0245458 A1
(43) Pub. Date: Jul. 30, 2020

(54) BASE MATERIAL FOR PRINTED CIRCUIT BOARD AND PRINTED CIRCUIT BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Kazuhiro MIYATA, Osaka (JP); Motohiko SUGIURA, Osaka (JP); Masamichi YAMAMOTO, Osaka (JP)

(21) Appl. No.: 16/648,034

(22) PCT Filed: Jul. 9, 2018
(86) PCT No.: PCT/JP2018/025835

§ 371 Date: Mar. 17, 2020

(30) Foreign Application Priority Data
Oct. 16, 2017 (JP) 2017-200462

(51) Int. Cl. H05K 1/09; H05K 1/03

(52) U.S. Cl. CPC H05K 1/09; B22F 7/04; H05K 2201/0338; H05K 1/0393

(57) ABSTRACT

According to one aspect of the present disclosure, a base material for a printed circuit board includes: an insulating base film; a sintered body layer that is layered on at least one surface of the base film and that is formed of a plurality of sintered metal particles; and an electroless plating layer that is layered on a surface of the sintered body layer that is opposite to the base film, wherein an area rate of sintered bodies of the metal particles in a cross section of the sintered body layer is greater than or equal to 50% and less than or equal to 90%.

### TECHNICAL FIELD

The present invention relates to a base material for a printed circuit board and a printed circuit board. The present application is based on and claims priority to Japanese Patent Application No. 2017-200462, filed on Oct. 16, 2017, the entire contents of the Japanese Patent Application are hereby incorporated herein by reference.

### BACKGROUND ART

A base material for a printed circuit board is widely used which includes a metal layer on a surface of an insulating base film and for obtaining a flexible printed circuit board by forming a conductive pattern by etching the metal layer.

In recent years, in accordance with reduction in size and higher performance of electronic devices, higher-density printed circuit boards are demanded. As a base material for a printed circuit board that satisfies the demand for a higher density as described above, a base material for a printed circuit board in which the thickness of a conductive layer is reduced is required.

Also, a base material for a printed circuit board is required to have a high peel strength between the base film and the metal layer so that the metal layer is not peeled from the base film when a bending stress is applied to the flexible printed circuit board.

In response to such a demand, a base material for a printed circuit board is proposed in which a first conductive layer is formed by applying and sintering to the surface of an insulating base material (base film) of a conductive ink containing metal particles and a metal deactivator, an electroless plating layer is formed by applying electroless plating to the first conductive layer, and a second conductive layer is formed by electroplating on the electroless plating layer (see Japanese Laid-open Patent Publication No. 2012-114152).

### PRIOR ART DOCUMENT

### Patent Document

[Patent Document 1] Japanese Laid-open Patent Publication No. 2012-114152

### SUMMARY OF THE INVENTION

According to one aspect of the present disclosure, a base material for a printed circuit board includes: an insulating base film; a sintered body layer that is layered on at least one surface of the base film and that is formed of a plurality of sintered metal particles; and an electroless plating layer that is layered on a surface of the sintered body layer that is opposite to the base film, wherein an area rate of sintered bodies of the metal particles in a cross section of the sintered body layer is greater than or equal to 50% and less than or equal to 90%.

According to one aspect of the present disclosure, a printed circuit board includes: an insulating base film; a sintered body layer that is layered on at least one surface of the base film and that is formed of a plurality of sintered metal particles; an electroless plating layer that is layered on a surface of the sintered body layer that is opposite to the base film; and an electroplating layer that is layered on a surface of the electroless plating layer that is opposite to the sintered body layer, wherein the sintered body layer, the electroless plating layer, and the electroplating layer are patterned in plan view, and wherein an area rate of sintered bodies of the metal particles in a cross section of the sintered body layer is greater than or equal to 50% and less than or equal to 90%.

### BRIEF DESCRIPTION OF THE DRAWINGS

FIG. 1 is a schematic cross-sectional view illustrating a base material for a printed circuit board according to one embodiment of the present disclosure; and

FIG. 2 is a schematic cross-sectional view illustrating a printed circuit board according to one embodiment of the present disclosure.

### EMBODIMENT FOR CARRYING OUT THE INVENTION

### Problem to Be Solved by the Present Disclosure

In the base material for a printed circuit board described in the above described patent publication, because the metal layer is directly layered on the surface of the insulating base material without using an adhesive, the thickness can be reduced. Also, by containing the metal deactivator in the sintered layer, the base material for a printed circuit board described in the above described patent publication prevents a decrease in the peel strength of the metal layer due to diffusion of metal ions. Also, the base material for a printed circuit board disclosed in the publication can be manufactured without any special facility such as a vacuum facility, and thus can be provided at a relatively low cost.

However, the inventors of the present invention have tested and found that upon holding the base material for a printed circuit board described in the above described publications in a high temperature environment for a long time, the peel strength of the metal layer may decrease due to thermal aging.

In view of above, the present disclosure has an object to provide a base material for a printed circuit board and a printed circuit board such that a decrease in peel strength of a base film and the metal layer due to thermal aging is small.

### Effect of the Present Disclosure

According to a base material for a printed circuit board according to one aspect of the present disclosure and a printed circuit board according to another aspect of the present disclosure, a decrease in the peel strength between the base film and the metal layer due to thermal aging is small.

### DESCRIPTION OF EMBODIMENTS OF THE PRESENT DISCLOSURE

According to one aspect of the present disclosure, a base material for a printed circuit board includes: an insulating base film; a sintered body layer that is layered on at least one surface of the base film and that is formed of a plurality of sintered metal particles; and an electroless plating layer that is layered on a surface of the sintered body layer that is opposite to the base film, wherein an area rate of sintered bodies of the metal particles in a cross section of the sintered body layer is greater than or equal to 50% and less than or equal to 90%.

According to the base material for a printed circuit board, by the area rate of the sintered bodies of the metal particles in a cross section of the sintered body layer being in the above described range, without impairing the strength of the sintered body layer or the base film due to excessive heat at the time of sintering, it is possible to enhance the peel strength between the base film and the sintered body layer, and in particular, it is possible to reduce a decrease in the peel strength due to thermal aging in a high-temperature environment. Also, the base material for a printed circuit board can be manufactured without any special facility such as a vacuum facility, and thus can be manufactured at a relatively low cost despite that the peel strength between the base film and the metal layer, which is the sintered body layer, is large.

In the base material for a printed circuit board, it is preferable that an average particle size of the metal particles is greater than or equal to 1 nm and less than or equal to 500 nm. In this way, by the metal particles having an average particle size within the range described above, the dense sintered body layer having a low porosity can be relatively easily formed, and the peel strength between the base film and the metal layer can be further enhanced.

In the base material for a printed circuit board, it is preferable that a main component of the metal particles and an electroless plating metal of the electroless plating layer is copper. In this way, by the main component of the metal particles and the electroless plating metal being copper or a copper alloy, it is possible to form a metal layer having a relatively excellent conductivity at low cost.

Also, according to another aspect of the present disclosure, a printed circuit board includes: an insulating base film; a sintered body layer that is layered on at least one surface of the base film and that is formed of a plurality of sintered metal particles; an electroless plating layer that is layered on a surface of the sintered body layer that is opposite to the base film; and an electroplating layer that is layered on a surface of the electroless plating layer that is opposite to the sintered body layer, wherein the sintered body layer, the electroless plating layer, and the electroplating layer are patterned in plan view, and wherein an area rate of sintered bodies of the metal particles in a cross section of the sintered body layer is greater than or equal to 50% and less than or equal to 90%.

According to the printed circuit board, by the area rate of the sintered bodies of the metal particles in a cross section of the sintered body layer being in the above described range, a decrease in the peel strength between the base film and the metal layer due to thermal aging is small.

Here, the term “area rate of the sintered bodies of the metal particles” is the area rate of the metal particles on a scanning electron microscope observation image of a cross section. Also, the term “sintering” includes not only making a completely sintered state in which particles are tightly bonded together but also includes a state in which particles are at a stage before reaching a completely sintered state and adhere to each other to form solid bonds. Also, the term “average particle size” is the average value of the equivalent circle diameters of particles in a scanning electron microscope observation image in a cross section. Also, the term “main component” is a component whose content by mass is the largest, and is preferably a component whose content is greater than or equal to 90% by mass.

[Details of Embodiment of the Present Disclosure]

In the following, a base material for a printed circuit board according to each embodiment of the present disclosure will be described with reference to the drawings.

[Base Material for Printed Circuit Board]

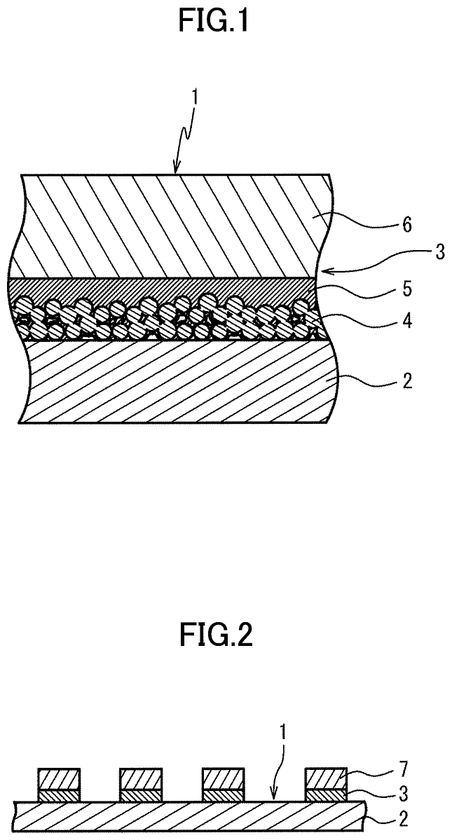

A base material 1 for a printed circuit board illustrated in FIG. 1 includes an insulating base film 2 and a metal layer 3 that is layered on one surface of the base film 2.

The metal layer 3 is includes a sintered body layer 4 that is layered on the one surface of the base film 2 and that is formed by sintering a plurality of metal particles, an electroless plating layer 5 that is formed on a surface of the sintered body layer 4 that is opposite to the base film 2, and an electroplating layer 6 that is layered on a surface of the electroless plating layer 5 that is opposite to the sintered body layer 4.

<Base Film>

Examples of a material of the base film 2 that can be used include flexible resins, such as polyimide, liquid-crystal polymers, fluororesins, polyethylene terephthalate, and polyethylene naphthalate; rigid materials, such as phenolic paper, epoxy paper, glass composites, glass epoxy, polytetrafluoroethylene, and glass base materials; rigid-flexible materials in which hard materials and soft materials are combined together, and the like. Among these, polyimide is particularly preferable because of having a high bonding strength to a metal oxide and the like.

The thickness of the base film 2 is set depending on a printed circuit board using the base material for a printed circuit board, and is not particularly limited. For example, the lower limit of the average thickness of the base film 2 is preferably 5 μm, and is more preferably 12 μm. In contrast, the upper limit of the average thickness of the base film 2 is preferably 2 mm, and is more preferably 1.6 mm. In a case in which the average thickness of the base film 2 is less than the lower limit, the strength of the base film 2 or the base material for a printed circuit board may become insufficient. On the contrary, in a case in which the average thickness of the base film 2 exceeds the upper limit, the base material for a printed circuit board may become unnecessarily thick.

It is preferable to apply a hydrophilic treatment to a surface of the base film 2 on which the sintered body layer 4 is layered. Examples of the hydrophilic treatment that can be employed include a plasma treatment by which a surface is irradiated with light to be hydrophilized; and an alkali treatment by which a surface is hydrophilized with an alkali solution. By applying the hydrophilic treatment to the base film 2, the adhesion to the sintered body layer 4 can be enhanced and the peel strength of the metal layer 3 can be enhanced. Also, in a case in which the sintered body layer 4 is formed by the application and sintering of an ink containing metal particles as described below, because the surface tension of the ink against the base film 2 is reduced, it becomes easy to uniformly apply the ink to the base film 2.

<Sintered Body Layer>

The sintered body layer 4 is formed and layered on the one surface of the base film 2 by sintering a plurality of metal particles. Also, the porosity of the sintered body layer 4 is reduced by filling gaps between the metal particles with a plating metal at the time of forming electroless plating layer 5.

The sintered body layer 4 can be formed by, for example, application and sintering of an ink containing the plurality of metal particles. In this way, by using the ink containing the metal particles, the metal layer 3 can be formed on the one surface of the base film 2 easily at a low cost.

As a metal to be a main component of the metal particles that form the sintered body layer 4, a metal is preferable such that a metal oxide derived from the metal or a group derived from the metal oxide and a metal hydroxide derived from the metal or a group derived from the metal hydroxide are generated in the vicinity of the interface of the sintered body layer 4 with the base film 2 of the base material for a printed circuit board, and copper (Cu), nickel (Ni), aluminum (Al), gold (Au), or silver (Ag) can be used. Among these, as a metal having a good conductivity and excellent in adhesion to the base film 2, copper is particularly preferably used.

The lower limit of the area rate of the sintered bodies of metal particles in a cross section of the sintered body layer 4 (not including the area of the plating metal filling the gaps of the metal particles at the time of forming the electroless plating layer 5) is preferably 50%, and is more preferably 60%. In contrast, the upper limit of the area rate of the sintered bodies of the metal particles in the cross section of the sintered body layer 4 is preferably 90%, and is more preferably 80%. In a case in which the area rate of the sintered bodies of the metal particles in the cross section of the sintered body layer 4 is less than the lower limit, the decrease in the peel strength due to thermal aging may not be sufficiently suppressed. On the contrary, in a case in which the area rate the sintered bodies of the metal particles in a cross section of the sintered body layer 4 exceeds the upper limit, the base film 2 or the like may be damaged due to an excessive heat required at the time of sintering, or the base material for a printed circuit board may become unnecessary high cost because the sintered body layer 4 becomes not easily formed.

The lower limit of the average particle size of the metal particles in the sintered body layer 4 is preferably 1 nm, and is more preferably 30 nm. In contrast, the upper limit of the average particle size of the metal particles is preferably 500 nm, and is more preferably 200 nm. In a case in which the average particle size of the metal particles is less than the lower limit, for example, due to a decrease in dispersibility and stability of the metal particles in the ink, uniform lamination may not be easily performed on the surface of the base film 2. On the contrary, in a case in which the average particle size of the metal particles exceeds the upper limit, gaps between the metal particles become larger and the porosity of the sintered body layer 4 may not be easily reduced.

The lower limit of the average thickness of the sintered body layer 4 is preferably 50 nm, and is more preferably 100 nm. In contrast, the upper limit of the average thickness of the sintered body layer 4 is preferably 2 μm, and is more preferably 1.5 μm. In a case in which the average thickness of the sintered body layer 4 is less than the lower limit, portions where the metal particles are not present increase in plan view, and the conductivity may decrease. On the contrary, in a case in which the average thickness of the sintered body layer 4 exceeds the upper limit, it may become difficult to sufficiently reduce the porosity of the sintered body layer 4 and the metal layer 3 may become unnecessarily thick.

In the vicinity of the interface between the base film 2 and the sintered body layer 4, the metal oxide derived from the metal of the metal particles or the group derived from the metal oxide (which may be referred to collectively as a “metal oxide or the like”), or the metal hydroxide derived from the metal or the group derived from the metal hydroxide (which may be referred to collectively as a “metal hydroxide or the like”) is preferably present. It is particularly preferable that both of the metal oxide and the metal hydroxide are present. This is because the metal oxide or the like and the metal hydroxide or the like are an oxide and a hydroxide that are generated based on the metal particles. The metal oxide or the like and the metal hydroxide or the like have a relatively high adhesion to the base film 2 formed of a resin or the like and to the sintered body layer 4 formed of the metal. Thus, the presence of the metal oxide or the like or the metal hydroxide or the like in the vicinity of the interface between the base film 2 and the sintered body layer 4 enhances the peel strength between the base film 2 and the sintered body layer 4. For example, in a case in which copper is used for the metal particles, copper oxide (CuO) or a group derived from the copper oxide and copper hydroxide (Cu(OH)₂) or a group derived from copper hydroxide may be formed and present in the vicinity of the interface between the base film 2 and the sintered body layer 4.

The lower limit of the amount of the metal oxide or the like present per unit area in the vicinity of the interface between the base film 2 and the sintered body layer 4 is preferably 0.1 μg/cm², and is more preferably 0.15 μg/cm². In contrast, the upper limit of the amount of the metal oxide or the like present per unit area is preferably 10 μg/cm², is more preferably 5 μg/cm², and is further more preferably 1 μg/cm². In a case in which the amount of the metal oxide or the like present per unit area is less than the lower limit, the effect of the metal oxide enhancing the peel strength between the base film 2 and the sintered body layer 4 may decrease. On the contrary, in a case in which the amount of the metal oxide or the like present per unit area exceeds the upper limit, it may be difficult to control sintering of the metal particles.

The lower limit of the amount of the metal hydroxide or the like present per unit area in the vicinity of the interface between the base film 2 and the sintered body layer 4 is preferably 0.5 μg/cm², and is more preferably 1.0 μg/cm². In contrast, the upper limit of the amount of the metal hydroxide or the like present per unit area is preferably 10 μg/cm², and is more preferably 5 μg/cm². In a case in which the amount of the metal hydroxide or the like present per unit area is less than the lower limit, it may be difficult to control sintering of the metal particles for generating a large amount of the metal oxide or the like. On the contrary, in a case in which the amount of the metal hydroxide or the like present per unit area exceeds the upper limit, because the metal oxide or the like is relatively reduced, the peel strength between the sintered body layer 4 and the base film 2 may not be enhanced by the metal oxide.

The lower limit of the presence ratio (mass ratio) of the amount of the metal oxide or the like present to the amount of the metal hydroxide or the like present in the vicinity of the interface of the base film 2 and the sintered body layer 4 is preferably 0.1, and is more preferably 0.2. In contrast, the upper limit of the presence ratio is preferably 5, is more preferably 3, and is further more preferably 1. In a case in which the presence ratio is less than the lower limit, because the amount of the metal hydroxide or the like is excessively large with respect to the amount of the metal oxide or the like in the vicinity of the interface, the peel strength between the base film 2 and the sintered body layer 4 may not be enhanced. On the contrary, in a case in which the presence ratio exceeds the upper limit, it may be difficult to control sintering of the metal particles.

<Electroless Plating Layer>

The electroless plating layer 5 is formed by applying electroless plating to the outer surface of the sintered body layer 4. Also, the electroless plating layer 5 is formed to be impregnated with the sintered body layer 4. That is, by filling gaps between the metal particles that form the sintered body layer 4 with an electroless plating metal, pores inside the sintered body layer 4 are reduced. By reducing the pores between the metal particles, it is possible to inhibit the peeling of the sintered body layer 4 from the base film 2 due to the pores acting as fracture starting points.

As a metal that is used for the electroless plating, for example, copper, nickel, silver, or the like having a good conductivity can be used, and in a case in which copper is used for the metal particles that form the sintered body layer 4, copper is preferably used in view of cost and adhesion to the sintered body layer 4.

In some cases, depending on the conditions of the electroless plating, the electroless plating layer 5 is formed only inside the sintered body layer 4. However, the lower limit of the average thickness (not including the thickness of the electroless plating layer inside the sintered body layer 4) of the electroless plating layer 5 that is formed on the outer surface of the sintered body layer 4 is preferably 0.2 μm, and is more preferably 0.3 μm. In contrast, the upper limit of the average thickness of the electroless plating layer 5 that is formed on the outer surface of the sintered body layer 4 is preferably 1 μm, and is more preferably 0.5 μm. In a case in which the average thickness of the electroless plating layer 5 that is formed on the outer surface of the sintered body layer 4 is less than the lower limit, the gaps between the metal particles in the sintered body layer 4 are not sufficiently filled with the electroless plating layer 5, and the porosity cannot be sufficiently reduced. Therefore, the peel strength between the base film 2 and the metal layer 3 may become insufficient. On the contrary, in a case in which the average thickness of the electroless plating layer 5 that is formed on the outer surface of the sintered body layer 4 exceeds the upper limit, the time required for the electroless plating increases, and the manufacturing cost may unnecessarily increase.

<Electroplating Layer>

The electroplating layer 6 is layered on the outer surface side of the sintered body layer 4, which is the outer surface of the electroless plating layer 5, by electroplating. Due to the electroplating layer 6, the thickness of the metal layer 3 can be easily and accurately adjusted. Also, by using electroplating, it is possible to increase the thickness of the metal layer 3 in a short time.

As a metal that is used for the electroplating, for example, copper, nickel, silver, or the like having a good conductivity can be used. Among these, copper or nickel that is inexpensive and excellent in conductivity is particularly preferable.

The thickness of the electroplating layer 6 is set in accordance with on the type and thickness of a conductive pattern required for a printed circuit board that is formed by using the base material 1 for a printed circuit board, and is not particularly limited. Typically, the lower limit of the average thickness of the electroplating layer 6 is preferably 1 μm, and is more preferably 2 μm. In contrast, the upper limit of the average thickness of the electroplating layer 6 is preferably 100 μm, and is more preferably 50 μm. In a case in which the average thickness of the electroplating layer 6 is less than the lower limit, the metal layer 3 may be easily damaged. On the contrary, in a case in which the average thickness of the electroplating layer 6 exceeds the upper limit, the base material 1 for a printed circuit board may become unnecessarily thick, and the flexibility of the base material 1 for a printed circuit board may become insufficient.

[Method of Manufacturing Base material for Printed Circuit Board]

A method of manufacturing the base material for a printed circuit board includes a step of forming metal particles, a step of preparing an ink with the metal particles formed in the metal particle formation step, a step of applying the ink obtained in the ink preparation step to one surface of the insulating base film 2, a step of drying coating of the ink formed in the application step, a step of sintering the dried coating of the ink, a step of applying electroless plating to the outer surface of the sintered body layer 4 formed in the sintering step, and a step of applying electroplating to the outer surface side of the sintered body layer 4 (outer surface of the electroless plating layer).

<Metal Particle Formation Step>

Examples of a method of forming the metal particles in the metal particle formation step include a high-temperature treatment method, a liquid-phase reduction method, a gas-phase method, and the like. Among these, the liquid-phase reduction method is preferably used in which metal ions are reduced with a reducing agent in an aqueous solution to precipitate metal particles.

A specific method of forming the metal particles by the liquid-phase reduction method can be, for example, a method that includes a reduction step of subjecting metal ions to a reduction reaction with a reducing agent for a certain period of time in a solution obtained by dissolving, in water, a dispersant and a water-soluble metal compound to be an origin of metal ions that form the metal particles.

As the water-soluble metal compound to be the origin of the metal ions, for example, in the case of copper, copper(II) nitrate (Cu(NO₃)₂), copper(II) sulfate pentahydrate (CuSO₄.5H₂O), or the like can be used. Also, in the case of silver, silver(I) nitrate (AgNO₃), silver methanesulfonate (CH₃SO₃Ag), or the like, in the case of gold, hydrogen tetrachloroaurate(III) tetrahydrate (HAuCl₄.4H₂O), or the like, can be used. In the case of nickel, nickel(II) chloride hexahydrate (NiCl₂.6H₂O), nickel(II) nitrate hexahydrate (Ni(NO₃)₂.6H₂O), or the like can be used. For other metal particles, water-soluble compounds such as chlorides, nitrate compounds, and sulfate compounds can also be used.

As the reducing agent in a case in which metal particles are formed by the liquid-phase reduction method, various reducing agents capable of reducing and precipitating the metal ions in the reaction system of a liquid phase (aqueous solution) can be used. Examples of the reducing agent include sodium borohydride, sodium hypophosphite, hydrazine, transition metal ions such as trivalent titanium ions and divalent cobalt ions, ascorbic acid, reducing sugars such as glucose and fructose, polyhydric alcohols such as ethylene glycol and glycerol, and the like.

Among these, a method in which metal ions are reduced to precipitate metal particles by redox action when trivalent titanium ions are oxidized to tetravalent titanium ions is a titanium redox method. Metal particles that are obtained by the titanium redox method have small and uniform particle sizes and have a shape similar to a spherical shape. Therefore, it is possible to form a dense layer of metal particles and to easily reduce the pores of the sintered body layer 4.

To adjust the particle sizes of the metal particles, the types and the mixing ratio of the metal compound, the dispersant, and the reducing agent may be adjusted, and the stirring rate, the temperature, the time, the pH, and the like in the reduction step of subjecting the metal compound to a reduction reaction may be adjusted.

In particular, the lower limit of the temperature in the reduction step is preferably 0° C., and is more preferably 15° C. In contrast, the upper limit of the temperature in the reduction step is preferably 100° C., is more preferably 60° C., and is further more preferably 50° C. In a case in which the temperature in the reduction step is lower than the lower limit, the reduction reaction efficiency may be insufficient. On the contrary, in a case in which the temperature in the reduction step exceeds the upper limit, the growth rate of the metal particles is large and the particle sizes may not be easily adjusted.

To obtain metal particles having small particle sizes as in the present embodiment, the pH of the reaction system in the reduction step is preferably greater than or equal to 7 and less than or equal to 13. At this time, by using a pH modifier, it is possible to adjust the pH of the reaction system in the range described above. Examples of the pH modifier that can be used include common acids and alkalis, such as hydrochloric acid, sulfuric acid, sodium hydroxide, and sodium carbonate. In particular, to prevent the degradation of peripheral members, nitric acid and ammonia, which does not contain impurity elements such as alkali metals, alkaline-earth metals, halogen elements such as chlorine, sulfur, phosphorus, and boron, are preferable.

<Ink Preparation Step>

In the ink preparation step, an ink containing the metal particles that form the sintered body layer 4 is prepared. As the ink containing the metal particles, an ink containing a dispersion medium for the metal particles and a dispersant that uniformly disperses the metal particles in the dispersion medium is preferably used. In this way, by using the ink in which the metal particles are uniformly dispersed, it is possible to uniformly attach the metal particles to the surface of the base film 2, and it is possible to form a uniform sintered body layer 4 on the surface of the base film 2.

Although the dispersant that is contained in the ink is not particularly limited, a polymeric dispersant whose molecular weight is greater than or equal to 100 and less than or equal to 300,000 is preferably used. In this way, by using the polymeric dispersant having a molecular weight within the range described above, it is possible to disperse the metal particles satisfactorily in the dispersion medium, and it is possible to make the film quality of the obtained sintered body layer 4 dense and defect-free. In a case in which the molecular weight of the dispersant is less than the lower limit, the effect of preventing the aggregation of the metal particles to maintain the dispersion may not be sufficiently obtained. As a result, a dense sintered body layer having few defects may not be layered on the base film 2. On the contrary, in a case in which the molecular weight of the dispersant exceeds the upper limit, the dispersant may become excessively bulky, and in the sintering step after applying the ink, sintering of the metal particles may be inhibited and voids may be generated. Also, when the dispersant is excessively bulky, the denseness of the film quality of the sintered body layer 4 may be decreased, and the decomposition residues of the dispersant may decrease the conductivity.

It is preferable that the dispersant does not contain sulfur, phosphorus, boron, halogens, and alkalis in terms of preventing the degradation of components. Preferable examples of the dispersant, having a molecular weight within the range described above, include amine-based polymeric dispersants such as polyethyleneimine and polyvinylpyrrolidone; hydrocarbon-based polymeric dispersants having a carboxylic acid group in its molecule, such as polyacrylic acid and carboxymethyl cellulose; polymeric dispersants having a polar group, such as Poval (polyvinyl alcohol), styrene-maleic acid copolymers, olefin-maleic acid copolymers, and copolymers having a polyethyleneimine moiety and a polyethylene oxide moiety in one molecule thereof.

The dispersant can also be added to the reaction system in a state of a solution dissolved in water or a water-soluble organic solvent. The content of the dispersant is preferably greater than or equal to 1 part by mass and less than or equal to 60 parts by mass per 100 parts by mass of the metal particles. Although the dispersant surrounds the metal particles to prevent aggregation of the metal particles, and satisfactorily disperses the metal particles, in a case in which the content of the dispersant is less than the lower limit, the effect of preventing the aggregation may become insufficient. On the contrary, in a case in which the content of the dispersant exceeds the upper limit, in the sintering step after applying the ink, an excessive dispersant may inhibit sintering of the metal particles and voids may be generated. Further, the decomposition residues of the polymeric dispersant may remain as impurities in the sintered body layer to decrease the conductivity.

The content of water to be a dispersion medium in the ink is preferably greater than or equal to 20 parts by mass and less than or equal to 1,900 parts by mass per 100 parts by mass of the metal particles. Although water as the dispersion medium sufficiently swells the dispersant to satisfactorily disperse the metal particles surrounded by the dispersant, in a case in which the content of water is less than the lower limit, the effect by water of swelling the dispersant may become insufficient. In a case in which the content of water exceeds the upper limit, the proportion of the metal particles in the ink is small, and it may be impossible to form a satisfactory sintered body layer having a necessary thickness and density on the surface of the base film 2.

As an organic solvent contained in the ink as needed, various water-soluble organic solvents can be used. Specific examples thereof include alcohols such as methyl alcohol, ethyl alcohol, n-propyl alcohol, isopropyl alcohol, n-butyl alcohol, isobutyl alcohol, sec-butyl alcohol, and tert-butyl alcohol; ketones such as acetone and methyl ethyl ketone; polyhydric alcohols such as ethylene glycol and glycerin, and other esters; glycol ethers such as ethylene glycol monoethyl ether and diethylene glycol monobutyl ether, and the like.

The content of the water-soluble organic solvent is preferably greater than or equal to 30 parts by mass and less than or equal to 900 parts by mass per 100 parts by mass of the metal particles. In a case in which the content of the water-soluble organic solvent is less than the lower limit, the effect by the organic solvent of adjusting the viscosity and adjusting the vapor pressure of the dispersion liquid may not be sufficiently obtained. On the contrary, in a case in which the content of the water-soluble organic solvent exceeds the upper limit, the effect by water of swelling the dispersant may be insufficient, and aggregation of the metal particles in the ink may occur.

It should be noted that in the case of manufacturing the metal particles by the liquid-phase reduction method, the metal particles precipitated in a liquid-phase reaction system (aqueous solution) can be prepared by using an ink that has been made into a powder through steps of filtration, washing, drying, disintegration, and the like. In this case, the powdery metal particles, water that is a dispersion medium, a dispersant, and, optionally, a water-soluble organic solvent can be mixed at predetermined proportions to prepare the ink containing the metal particles. However, it is preferable to prepare the ink with a liquid phase (aqueous solution), in which the metal particles have been precipitated, as a starting material. Specifically, the liquid phase (aqueous solution) containing the precipitated metal particles is subjected to treatment, such as ultrafiltration, centrifugal separation, washing with water, or electrodialysis, to remove impurities and, optionally, is concentrated to remove water. Alternatively, after water is added to adjust the concentration of the metal particles, and, optionally, a water-soluble organic solvent is further added at a predetermined proportion, thereby preparing the ink containing the metal particles. By this method, it is possible to prevent generation of coarse and irregular particles due to aggregation at the time of drying the metal particles, and it is easy to form a dense and uniform sintered body layer 4.

<Application Step>

In the application step, the ink is applied to one surface of the base film 2. As a method of applying the ink, for example, a known coating method, such as a spin coating method, a spray coating method, a bar coating method, a die coating method, a slit coating method, a roll coating method, or a dip coating method, can be used. Also, the ink may be applied to only part of one surface of the base film 2 by screen printing or with a dispenser or the like.

<Drying Step>

In the drying step, the coating of ink on the base film 2 is dried. Here, as the time from the coating to the drying of the ink is made reduced, the area rate of the sintered bodies of the metal particles in a cross section of the sintered body layer 4 obtained by sintering the coating in the subsequent sintering step can be increased.

In the drying step, it is preferable to promote drying of the ink by heating or blowing, and it is more preferable to dry the coating by blowing hot air onto the coating of the ink. The temperature of the hot air is preferably such that the solvent of the ink does not boil. A specific temperature of the hot air, for example, can be greater than or equal to 30° C. and less than or equal to 80° C. Also, it is preferable that the wind velocity of the hot air is such that the coating is ruffled. For example, a specific wind velocity on the coating surface of the hot air can be greater than or equal to 5 m/s and less than or equal to 10 m/s. Also, in order to reduce the time of drying an ink, it is preferable to use an ink of which solvent has a low boiling point.

<Sintering Step>

In the sintering step, the coating of the ink dried on the base film 2 in the drying step is sintered by a heat treatment. Thereby, the dispersant in the solvent of the ink is evaporated or thermally decomposed, the remaining metal particles are sintered, and the sintered body layer 4 fixed on one surface of the base film 2 is obtained.

Also, in the vicinity of the interface of the sintered body layer 4 with the base film 2, the metal particles are oxidized at the time of sintering, while suppressing generation of a metal hydroxide derived from the metal of the metal particles or a group derived from the metal hydroxide, a metal oxide derived from the metal or a group derived from the metal oxide is generated. Specifically, for example, in a case in which copper is used for metal particles, copper oxide and copper hydroxide are generated in the vicinity of the interface of the sintered body layer 4 with the base film 2. Because the copper oxide generated in the vicinity of the interface of the sintered body layer 4 is strongly bonded to polyimide constituting the base film 2, the peel strength between the base film 2 and the sintered body layer 4 increases.

The sintering is preferably performed in an atmosphere containing a certain amount of oxygen. The lower limit of the oxygen concentration in the atmosphere at the time of sintering is preferably 1 ppm by volume, and is more preferably 10 ppm by volume. In contrast, the upper limit of the oxygen concentration is preferably 10,000 ppm by volume, and is more preferably 1,000 ppm by volume. In a case in which the oxygen concentration is less than the lower limit, the amount of copper oxide generated in the vicinity of the interface of the sintered body layer 4 may be small, and the adhesion between the base film 2 and the sintered body layer 4 may not be sufficiently enhanced. On the contrary, in a case in which the oxygen concentration exceeds the upper limit, the metal particles may be excessively oxidized, and the conductivity of the sintered body layer 4 may decrease.

The lower limit of the sintering temperature is preferably 150° C., and is more preferably 200° C. In contrast, the upper limit of the sintering temperature is preferably 500° C., and is more preferably 400° C. In a case in which the sintering temperature is lower than the lower limit, the amount of copper oxide generated in the vicinity of the interface of the sintered body layer 4 may be small, and the adhesion between the base film 2 and the sintered body layer 4 may not be sufficiently enhanced. In a case in which the sintering temperature exceeds the upper limit and the base film 2 is an organic resin such as polyimide, the base film 2 may deform.

<Electroless Plating Step>

In the electroless plating step, on a surface of the sintered body layer 4 layered on one surface the base film 2 in the sintering step that is opposite to the base film 2, electroless plating is applied to form the electroless plating layer 5.

It should be noted that the electroless plating is preferably performed together with treatment such as a cleaner step, a water-washing step, an acid treatment step, a water-washing step, a pre-dip step, an activator step, a water-washing step, a reduction step, and a water-washing step.

Also, it is preferable to further perform heat treatment after the electroless plating layer 5 is formed by the electroless plating. By applying the heat treatment after forming the electroless plating layer 5, the metal oxide or the like in the vicinity of the interface of the sintered body layer 4 with the base film 2 is further increased, and the adhesion between the base film 2 and the sintered body layer 4 is further increased. The temperature and the oxygen concentration in the heat treatment after the electroless plating can be similar to the sintering temperature and the oxygen concentration in the sintering step.

<Electroplating Step>

In the electroplating step, the electroplating layer 6 is layered on the outer surface of the electroless plating layer 5 by electroplating. In the electroplating step, the entire thickness of the metal layer 3 is increased to a desired thickness.

The electroplating can be performed, for example, using a known electroplating bath corresponding to a plating metal such as copper, nickel, or silver, and selecting appropriate conditions in such a manner that the metal layer 3 having a desired thickness is promptly formed without defects.

[Advantage]

According to the base material 1 for a printed circuit board, by the area rate of the sintered bodies of the metal particles in a cross section of the sintered body layer 4 being in the above described range, a decrease in the peel strength between the base film 2 and the metal layer 3 due to thermal aging is small.

Also, the base material 1 for a printed circuit board can be manufactured without any special facility such as a vacuum facility, and thus can be manufactured at a relatively low cost despite that the peel strength between the base film 2 and the metal layer 3 is large.

[Printed Circuit Board]

The printed circuit board is formed with a subtractive method or a semi-additive method using the base material 1 for a printed circuit board illustrated in FIG. 1. More specifically, the printed circuit board is manufactured by forming a conductive pattern with the subtractive method or the semi-additive method using the metal layer 3 of the base material 1 for a printed circuit board.

In the subtractive method, a film of a photosensitive resist is formed on the surface of the metal layer 3 of the base material 1 for a printed circuit board illustrated in FIG. 1. The resist is patterned so as to correspond to a conductive pattern by exposure, development, and the like. Subsequently, a portion of the metal layer 3 other than the conductive pattern is removed by etching with the patterned resist as a mask. Finally, by removing the remaining resist, the printed circuit board including the conductive pattern formed of the remaining portion of the metal layer 3 of the base material 1 for a printed circuit board is obtained.

In the semi-additive method, a film of a photosensitive resist is formed on the surface of the metal layer 3 of the base material 1 for a printed circuit board illustrated in FIG. 1. The resist is patterned by exposure, development, and the like to form an opening corresponding to a conductive pattern. Subsequently, a conductive layer is selectively layered by plating with the patterned resist as a mask using the metal layer 3 exposed in the opening of the mask as a seed layer. After the resist is peeled off, a surface of the conductive layer and a portion of the metal layer 3 where the conductive layer is not formed are removed by etching. Thereby, as illustrated in FIG. 2, the printed circuit board is obtained including the conductive pattern in which a conductive layer 7 is further layered on the remaining portion of the metal layer 3 of the base material 1 for a printed circuit board.

[Advantage]

Because the printed circuit board is manufactured by using the base material 1 for a printed circuit board, the adhesion between the base film 2 and the sintered body layer 4 is large and the peel strength between the base film 2 and the metal layer 3 is large, and thus the conductive pattern is not easily peeled.

Also, because the printed circuit board is formed by a common subtractive method or a semi-additive method using the inexpensive base material 1 for a printed circuit board and thus can be manufactured at a low cost.

### Other Embodiments

The embodiments disclosed above should be considered exemplary in all respects and not limiting. The scope of the present invention is not limited to configurations of the above described embodiments, but is indicated by claims and is intended to include all changes within the meaning and scope of equivalence with the claims.

In the base material for a printed circuit board, a metal layer may be formed on each surface of the base film.

The base material for a printed circuit board may be one that does not include an electroplating layer, particularly in a case of being used to manufacture a printed circuit board by a semi-additive method.

Also, the sintered body layer of the base material for a printed circuit board may be formed by layering and sintering the metal particles on a surface of the base film using another means without using an ink.

### Examples

Although the present disclosure will be described in detail with reference to Examples, the present disclosure is not limited to the description of Examples.

<Prototypes of Base Materials for Printed Circuit Boards>

In order to verify effects of the present disclosure, eleven types of base materials for printed circuit boards, prototypes No. 1 to No. 11, were manufactured with different manufacturing conditions.

(Prototype No. 1)

First, copper particles having an average particle size of 85 nm were used as metal particles and dispersed in water of a solvent to prepare an ink having a copper concentration of 26% by mass. Next, using a polyimide film (“Kapton EN-S”, manufactured by Du Pont-Toray Co., Ltd.) having an average thickness of 12 μm as an insulating base film, the ink was applied to one surface of the polyimide film. Using a dryer to blow a room temperature air onto the film surface in the vertical direction at the wind velocity of 7 m/s, drying was performed to form a dry coating having an average thickness of 0.15 μm, and similarly, a dry coating was also formed on the opposite surface. Subsequently, the polyimide film on which the dry coatings were formed was sintered at 350° C. for 30 minutes in a nitrogen atmosphere having an oxygen concentration of 10 ppm by volume to form a sintered body layer. Then, electroless plating of copper was applied to the sintered body layer to form an electroless plating layer having an average thickness of 0.3 μm from the outer surface of the sintered body layer. Further, a heat treatment was performed at 350° C. for 2 hours in a nitrogen atmosphere having an oxygen concentration of 150 ppm by volume. Thereafter, electroplating was performed to form an electroplating layer such that the entire metal layer had an average thickness of 18 μm. Thereby, Prototype No. 1 of a base material for a printed circuit board was obtained

(Prototype No. 2)

With the exception of using “APICAL NPI” manufactured by Kaneka Corporation instead of “Kapton EN-S” as an insulating base film, by a method similar to that of Prototype No. 1 of the base material for a printed circuit board described above, Prototype No. 2 of a base material for a printed circuit board was obtained.

(Prototype No. 3)

With the exception of using “UPILEX SGA” manufactured by Ube Industries, Ltd. instead of “Kapton EN-S” as an insulating base film, by a method similar to that of Prototype No. 1 of the base material for a printed circuit board described above, Prototype No. 3 of a base material for a printed circuit board was obtained.

(Prototype No. 4)

With the exception that the drying method after ink application was natural drying, by a method similar to that of Prototype No. 1 of the base material for a printed circuit board described above, Prototype No. 4 of a base material for a printed circuit board was obtained.

(Prototype No. 5)

With the exception of using “APICAL NPI” manufactured by Kaneka Corporation instead of “Kapton EN-S” as an insulating base film, by a method similar to that of Prototype No. 4 of the base material for a printed circuit board described above, Prototype No. 5 of a base material for a printed circuit board was obtained.

(Prototype No. 6)

With the exception of using “UPILEX SGA” manufactured by Ube Industries, Ltd. instead of “Kapton EN-S” as an insulating base film, by a method similar to that of Prototype No. 4 of the base material for a printed circuit board described above, Prototype No. 6 of a base material for a printed circuit board was obtained.

(Prototype No. 7)

With the exception that a dry coating having an average thickness of 0.3 μm was formed using copper particles having an average particle size of 30 nm for metal particles, by a method similar to that of Prototype No. 1 of the base material for a printed circuit board described above, Prototype No. 7 of a base material for a printed circuit board was obtained.

(Prototype No. 8)

With the exception that a dry coating having an average thickness of 0.3 μm was formed using copper particles having an average particle size of 150 nm for metal particles, by a method similar to that of Prototype No. 1 of the base material for a printed circuit board described above, Prototype No. 8 of a base material for a printed circuit board was obtained.

(Prototype No. 9)

With the exception that the wind velocity was 9 m/s on the polyimide film in the drying condition after ink application, by a method similar to that of Prototype No. 1 of the base material for a printed circuit board described above, Prototype No. 9 of a base material for a printed circuit board was obtained.

(Prototype No. 10)

With the exception that the dryer temperature was 70° C. in the drying condition after ink application, by a method similar to that of Prototype No. 1 of the base material for a printed circuit board described above, Prototype No. 10 of a base material for a printed circuit board was obtained.

(Prototype No. 11)

With the exception of using an electric heater for the drying method after ink application, by a method similar to that of Prototype No. 1 of the base material for a printed circuit board described above, Prototype No. 11 of a base material for a printed circuit board was obtained.

<Area Rate of Sintered Bodies>

With respect to each of Prototypes No. 1 to No. 11 of the base materials for printed circuit boards, using cross-sectional images observed by a scanning electron microscope, the area rate of the sintered bodies of the metal particles in the sintered body layer was calculated. It should be noted that as the scanning electron microscope, “ULTRA 55” manufactured by from ZEISS was used.

<Thermal Aging Test>

In order to check thermal aging, Prototypes No. 1 to No. 11 of the base materials for printed circuit boards were maintained in a thermostat at 150° C. for one week.

<Peel Strength>

With respect to each of Prototypes No. 1 to No. 11 of the base materials for printed circuit boards after the thermal aging test, the peel strength (g/cm) between the polyimide film and the metal layer of was measured. The peel strength was measured in accordance with JIS-C6471 (1995), and measured by a method in which the metal layer peeled off in a direction of 180° with respect to the polyimide film.

Table 1 below indicates the area rate of the sintered bodies and the peel strength after the thermal aging test for each of Prototypes No. 1 to No. 11 of the base materials for printed circuit boards.

TABLE 1

| | SINTERED BODY | PEEL STRENGTH AFTER |
|---|---|---|
| PROTOTYPE | AREA RATE [%] | THERMAL AGING TEST [N/cm] |
| No. 1 | 75 | 7.5 |
| No. 2 | 72 | 7.3 |
| No. 3 | 76 | 7.5 |
| No. 4 | 40 | 2.8 |
| No. 5 | 43 | 3.6 |
| No. 6 | 39 | 2.5 |
| No. 7 | 85 | 8.1 |
| No. 8 | 64 | 6.9 |
| No. 9 | 81 | 7.8 |
| No. 10 | 80 | 7.8 |
| No. 11 | 68 | 6.5 |

As described above, there was a correlation between the area rate of the sintered bodies and the peel strength after the thermal aging test. Specifically, Prototypes Nos. 1 to 3 and 7 to 11 with relatively large area rate of sintered bodies had relatively large peel strength after the thermal aging test, while Prototypes Nos. 4, 5, and 6 with relatively small area rate of sintered bodies had small peel strength after the thermal aging test.

### DESCRIPTION OF THE REFERENCE NUMERALS

1 base material for a printed circuit board
2 base film
3 metal layer
4 sintered body layer
5 electroless plating layer
6 electroplating layer
7 conductive layer

1. A base material for a printed circuit board comprising:
an insulating base film;
a sintered body layer that is layered on at least one surface of the base film and that is formed of a plurality of sintered metal particles; and
an electroless plating layer that is layered on a surface of the sintered body layer that is opposite to the base film,
wherein an area rate of sintered bodies of the metal particles in a cross section of the sintered body layer is greater than or equal to 50% and less than or equal to 90%.

2. The base material for a printed circuit board according to claim 1, wherein an average particle size of the metal particles is greater than or equal to 1 nm and less than or equal to 500 nm.

3. The base material for a printed circuit board according to claim 1, wherein a main component of the metal particles and an electroless plating metal of the electroless plating layer is copper.

4. A printed circuit board comprising:
an insulating base film;
a sintered body layer that is layered on at least one surface of the base film and that is formed of a plurality of sintered metal particles;
an electroless plating layer that is layered on a surface of the sintered body layer that is opposite to the base film; and
an electroplating layer that is layered on a surface of the electroless plating layer that is opposite to the sintered body layer,
wherein the sintered body layer, the electroless plating layer, and the electroplating layer are patterned in plan view, and
wherein an area rate of sintered bodies of the metal particles in a cross section of the sintered body layer is greater than or equal to 50% and less than or equal to 90%.
